(19) United States
(12) Patent Application Publication
(10) Pub. No.: US 2022/0064790 A1
(43) Pub. Date: Mar. 3, 2022

(54) VAPOR DEPOSITION DEVICE

(71) Applicant: SUMCO CORPORATION, Tokyo (JP)

(72) Inventors: Naoyuki WADA, Tokyo (JP); Yu MINAMIDE, Tokyo (JP)

(73) Assignee: SUMCO CORPORATION, Tokyo (JP)

(21) Appl. No.: 17/415,838

(22) PCT Filed: Nov. 5, 2019
(86) PCT No.: PCT/JP2019/043260

§ 371 Date: Jun. 18, 2021

(30) Foreign Application Priority Data
Dec. 27, 2018 (JP) 2018-244833

(51) Int. Cl. C23C 16/458; H01L 21/67; H01L 21/687; H01L 21/677

(52) U.S. Cl. CPC C23C 16/458; H01L 21/67201; H01L 21/68707; H01L 21/67196; H01L 21/67742; H01L 21/68742

(57) ABSTRACT

A vapor deposition device is provided that can perform CVD processing without using a carrier. A first robot is provided with a first blade at a tip, the first blade includes a first recess which supports the carrier and a second recess which supports the wafer. A load-lock chamber is provided with a holder which can support the carrier and the wafer.

### FIELD OF THE INVENTION

The present invention relates to a vapor deposition device used in manufacturing epitaxial wafers, for example.

### BACKGROUND OF THE INVENTION

In order to keep damage to a reverse face of a silicon wafer to a minimum in vapor deposition devices used in manufacturing epitaxial wafers, for example, transporting the silicon wafer through steps from a load-lock chamber to a reaction chamber in a state where the silicon wafer is mounted on a ring-shaped carrier has been proposed (Patent Literature 1).

In this type of vapor deposition device, whereas a before-treatment wafer is mounted on a ring-shaped carrier standing by in the load-lock chamber, an after-treatment wafer is transported from the reaction chamber to the load-lock chamber still mounted on a ring-shaped carrier.

### RELATED ART

### Patent Literature

Patent Literature 1: U.S. Patent Application No. 2017/0110352

### SUMMARY OF THE INVENTION

### Problems to Be Solved by the Invention

However, in the conventional vapor deposition device which transfers wafers by using ring-shaped carrier, there is a problem that the vapor deposition device cannot be used when the carrier is damaged or broken and cannot be used.

The present invention undertakes to solve the issue of providing a vapor deposition device that can perform CVD processing without using a carrier.

### Means for Solving the Problems

The present invention is a vapor deposition device which is provided with a ring-shaped carrier that supports an outer edge of a wafer, and which uses a plurality of the carriers to:

transport a plurality of before-treatment wafers from a wafer storage container, through a factory interface, load-lock chamber, and wafer transfer chamber, to a reaction chamber in that order, and

transport a plurality of after-treatment wafers from the reaction chamber, through the wafer transfer chamber, load-lock chamber, and factory interface, to the wafer storage container in that order,

and in which the load-lock chamber communicates with the factory interface via a first door and also communicates with the wafer transfer chamber via a second door,

the wafer transfer chamber communicates, via a gate valve, with the reaction chamber in which a CVD film is formed on the wafer,

the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber,

the factory interface is provided with a second robot that extracts a before-treatment wafer from the wafer storage container and mounts the wafer on a carrier standing by in the load-lock chamber, and also stores in the wafer storage container an after-treatment wafer mounted on the carrier that has been transported to the load-lock chamber, and

the load-lock chamber is provided with a holder that supports the carrier,

wherein the first robot is provided with a first blade at a tip,

the first blade comprises:

a first recess which supports the carrier; and

a second recess which is provided at a bottom surface of the first recess to support the wafer.

More preferably, in the present invention, the first recess is a recess corresponding to a part of the outer circumferential wall surface of the carrier, and the second recess is a recess corresponding to a part of an outer shape of the wafer.

More preferably, in the present invention, the first recess and the second recess are formed concentrically.

The present invention is a vapor deposition device which is provided with a ring-shaped carrier that supports an outer edge of a wafer, and which uses a plurality of the carriers to:

transport a plurality of before-treatment wafers from a wafer storage container, through a factory interface, load-lock chamber, and wafer transfer chamber, to a reaction chamber in that order, and

transport a plurality of after-treatment wafers from the reaction chamber, through the wafer transfer chamber, load-lock chamber, and factory interface, to the wafer storage container in that order,

and in which the load-lock chamber communicates with the factory interface via a first door and also communicates with the wafer transfer chamber via a second door,

the wafer transfer chamber communicates, via a gate valve, with the reaction chamber in which a CVD film is formed on the wafer,

the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber, and

the factory interface is provided with a second robot that extracts a before-treatment wafer from the wafer storage container and mounts the wafer on a carrier standing by in the load-lock chamber, and also stores in the wafer storage container an after-treatment wafer mounted on the carrier that has been transported to the load-lock chamber,

wherein the load-lock chamber is provided with a holder which can support the carrier and the wafer.

More preferably, in the present invention, the holder includes a carrier holder which supports the carrier and a wafer holder which supports the wafer.

More preferably, in the present invention, the carrier holder supports the carrier at at least two points on each of a left side and a right side,

the wafer holder supports the wafer at at least two points on each of a left side and a right side,

the points at which the wafer holder supports the wafer at on each of the left side and the right side is set outside the points at which the carrier holder supports the carrier on each of the left side and the right side.

More preferably, in the present invention, the first robot is provided with a first blade at a tip,

the first blade comprises:

a first recess which supports the carrier; and

a second recess which is provided at a bottom surface of the first recess to support the wafer.

The present invention is a vapor deposition device which is provided with a ring-shaped carrier that supports an outer edge of a wafer, and which uses a plurality of the carriers to:

transport a plurality of before-treatment wafers from a wafer storage container, through a factory interface, load-lock chamber, and wafer transfer chamber, to a reaction chamber in that order, and

transport a plurality of after-treatment wafers from the reaction chamber, through the wafer transfer chamber, load-lock chamber, and factory interface, to the wafer storage container in that order,

and in which the load-lock chamber communicates with the factory interface via a first door and also communicates with the wafer transfer chamber via a second door,

the wafer transfer chamber communicates, via a gate valve, with the reaction chamber in which a CVD film is formed on the wafer,

the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber,

the factory interface is provided with a second robot that extracts a before-treatment wafer from the wafer storage container and mounts the wafer on a carrier standing by in the load-lock chamber, and also stores in the wafer storage container an after-treatment wafer mounted on the carrier that has been transported to the load-lock chamber, and

the load-lock chamber is provided with a holder that supports the carrier,

wherein the reaction chamber is provided with a support shaft which supports a susceptor and rotates by a rotation drive unit and a lift shaft which moves up and down with respect to the support shaft by a lifting drive unit,

the lift shaft is provided with a first mounting portion on which a carrier lifting pin can be mounted and a second mounting portion on which a wafer lifting pin can be mounted,

the support shaft is provided with a first through hole through which the carrier lifting pin mounted on the first mounting portion can penetrate and a second through hole through which the wafer lifting pin mounted on the second mounting portion can penetrate.

More preferably, in the present invention, a shaft portion of the support shaft is inserted into a shaft portion of the lift shaft, and the lift shaft rotates and moves up and down together with the support shaft.

More preferably, in the present invention, the first robot is provided with a first blade at a tip,

the first blade comprises:

a first recess which supports the carrier; and

a second recess which is provided at a bottom surface of the first recess to support the wafer.

More preferably, in the present invention, the load-lock chamber is provided with a holder which can support the carrier and the wafer.

### Effect of the Invention

According to the present invention, the first blade provided at a tip of the first robot comprises a second recess which supports the wafer, the load-lock chamber is provided with a holder which can support the carrier and the wafer, or the support shaft is provided with a second through hole through which the wafer lifting pin can penetrate. Therefore, only the wafer can be transported and subjected to CVD processing. As a result, the vapor deposition process can be performed without using the carrier.

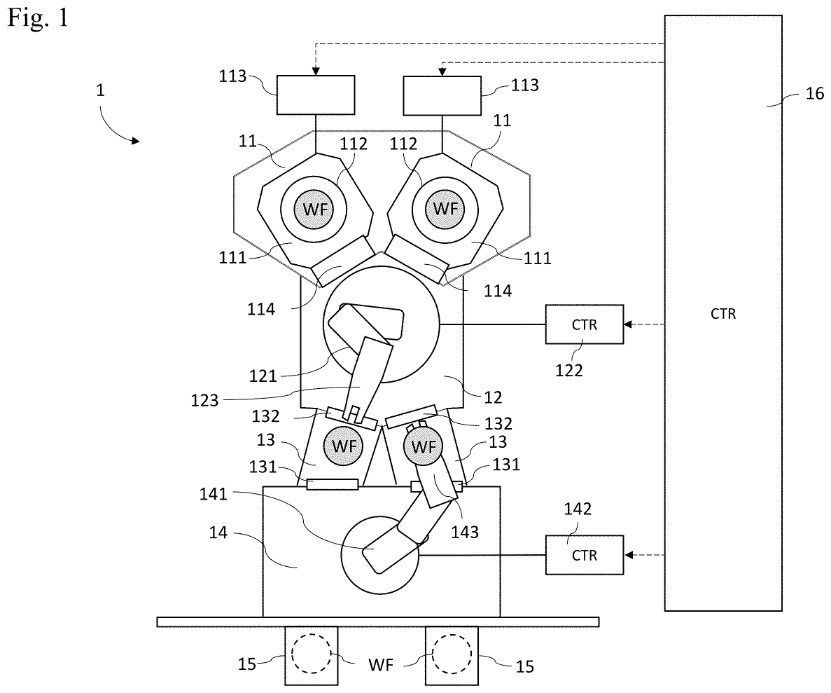

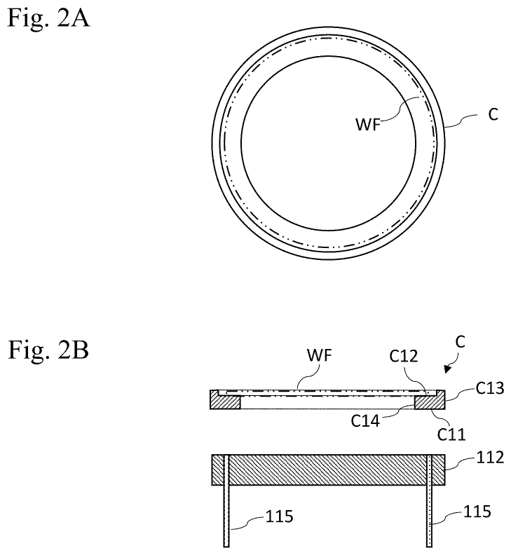

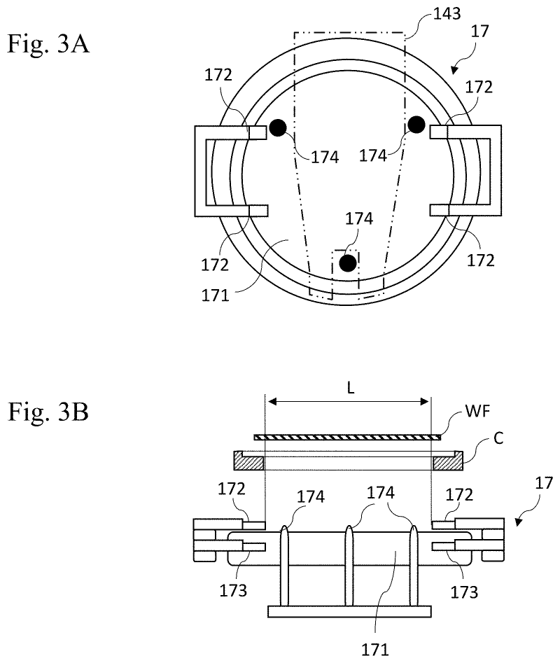

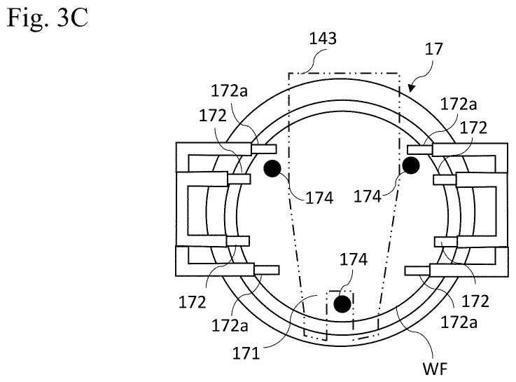

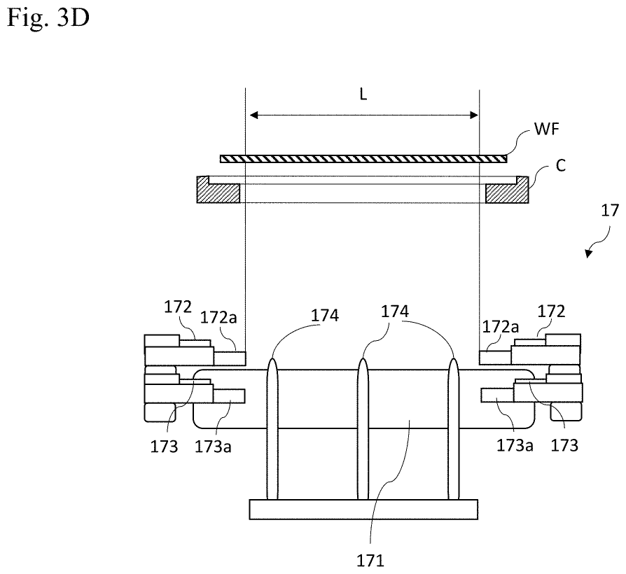

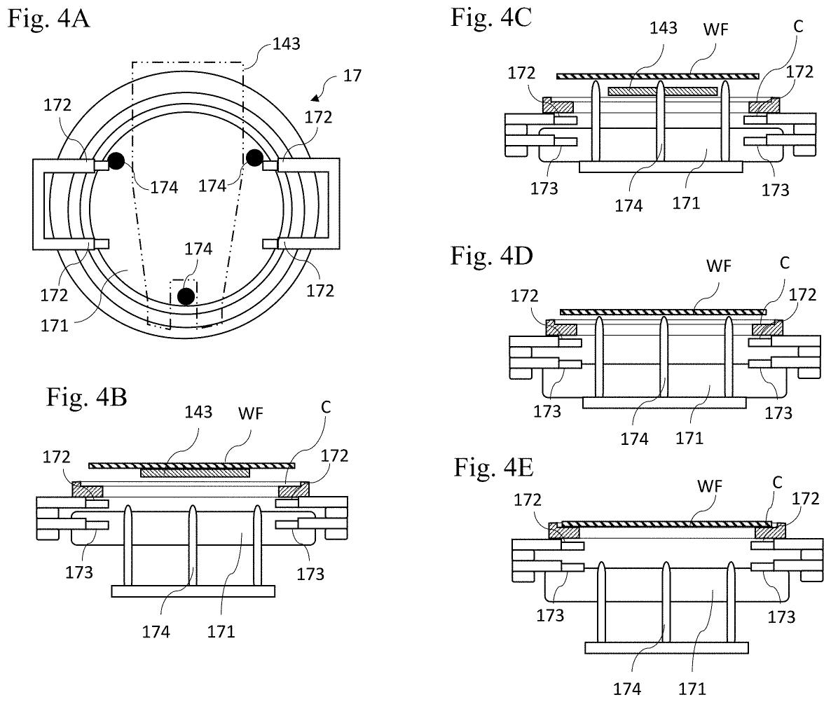

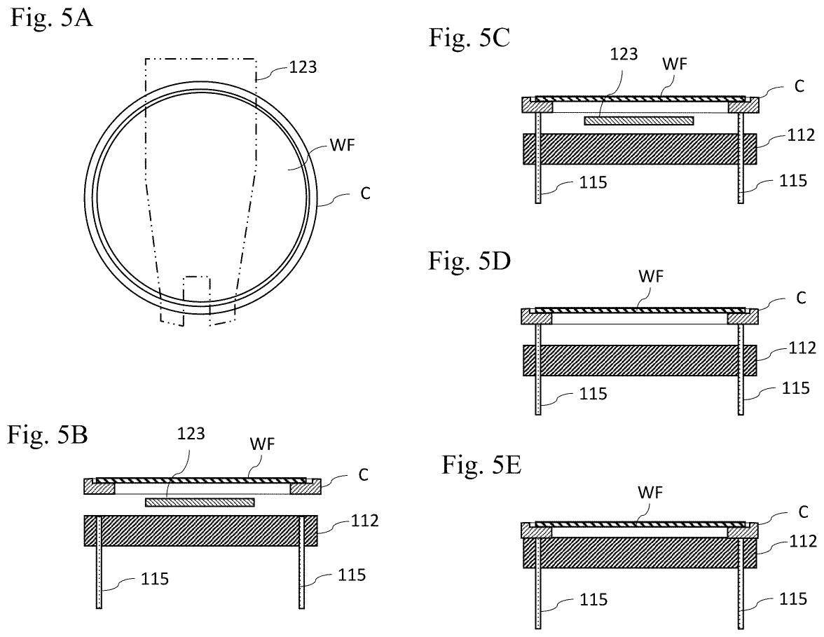

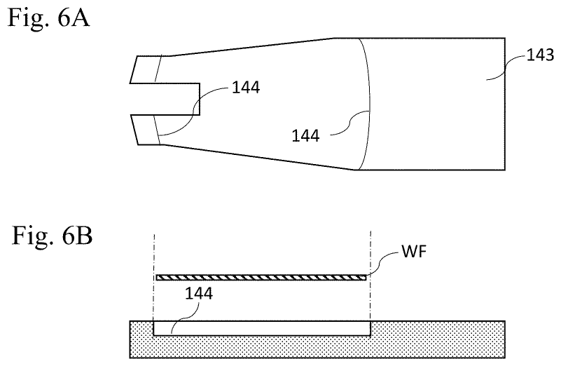

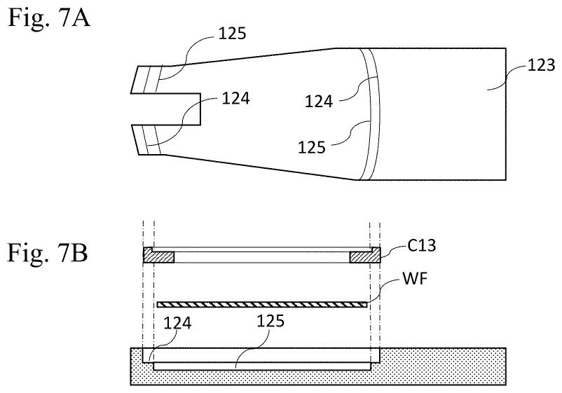

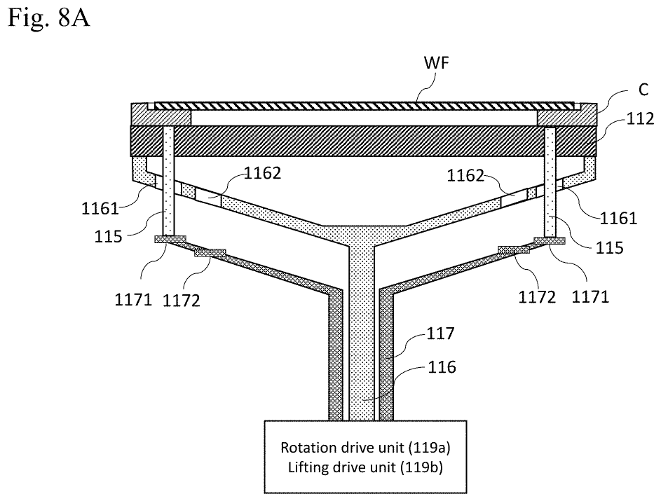

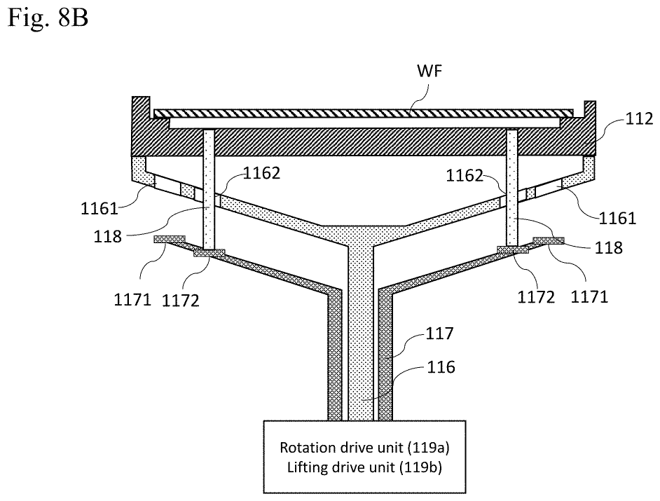

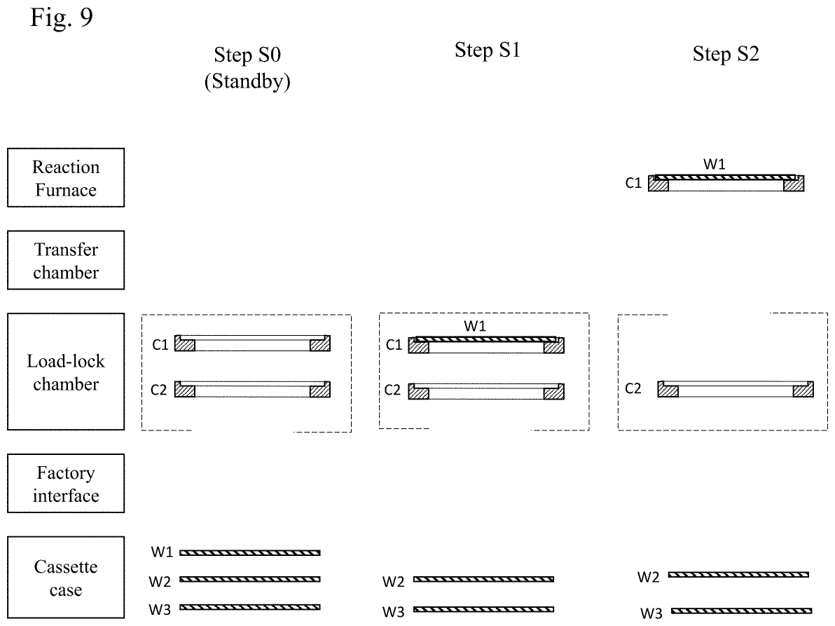

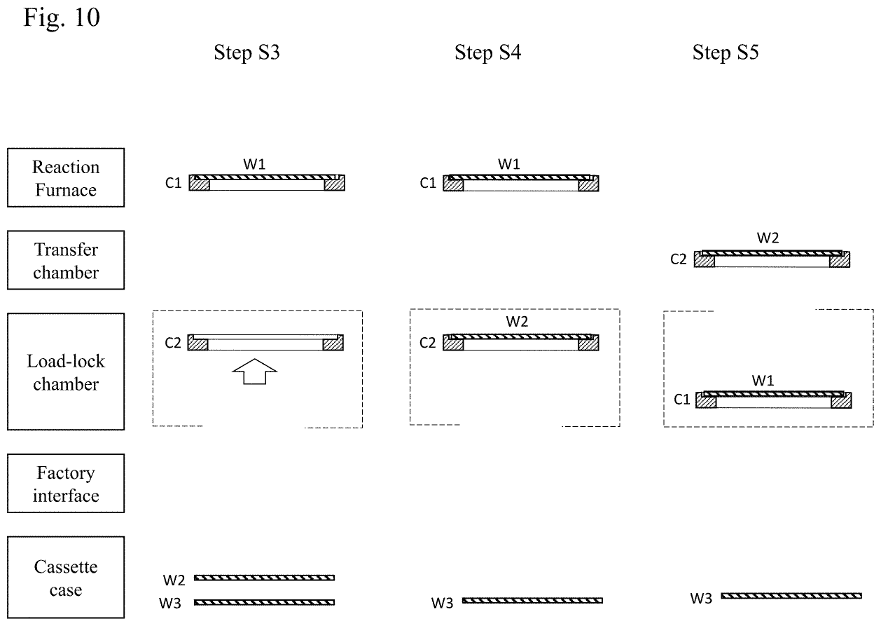

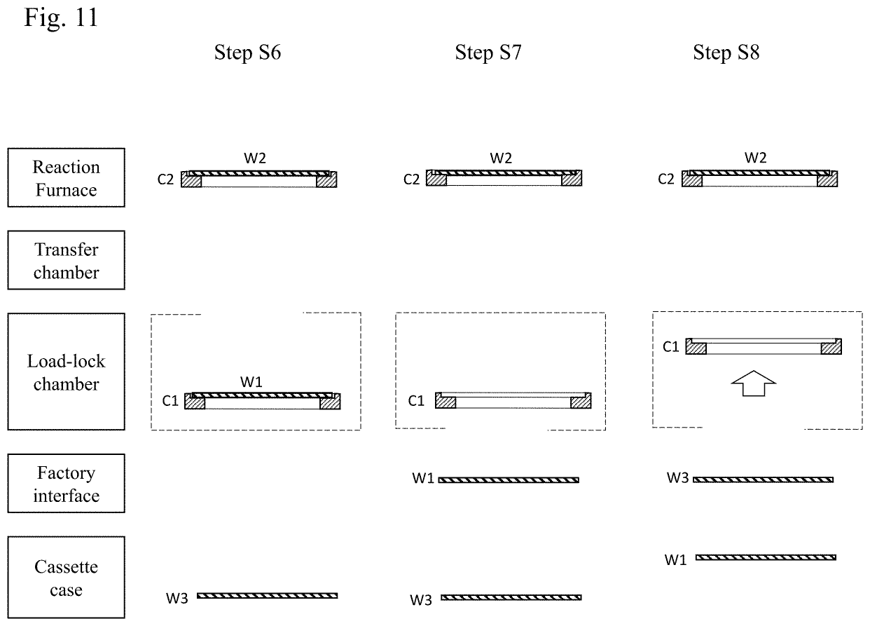

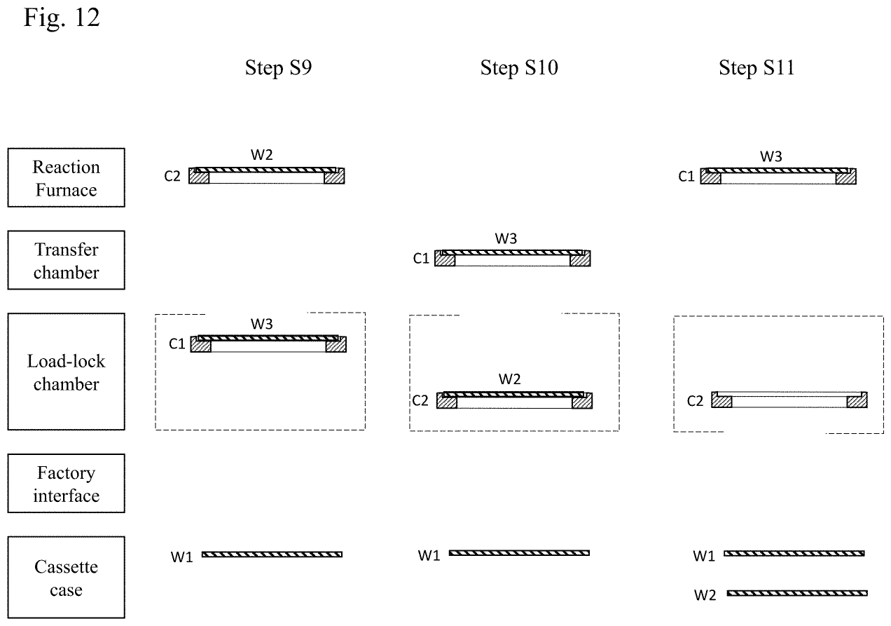

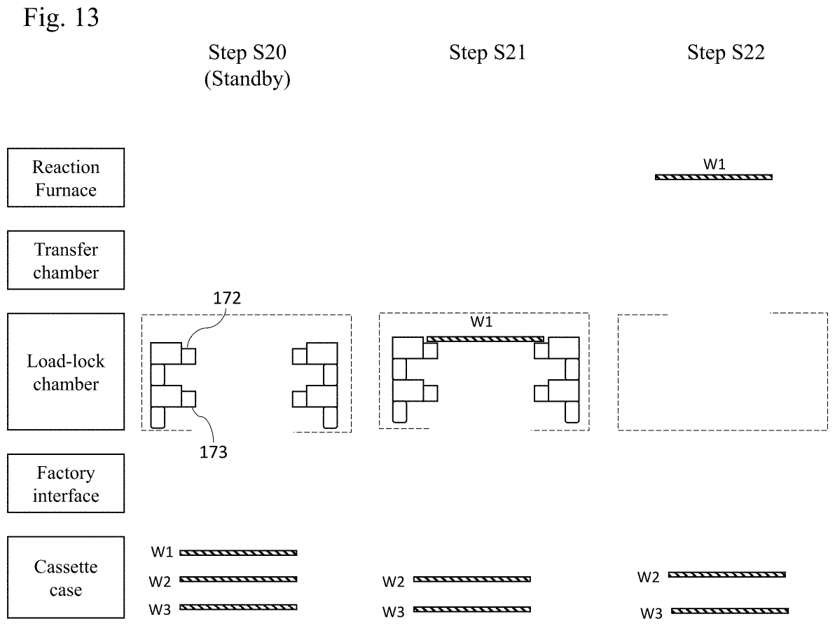

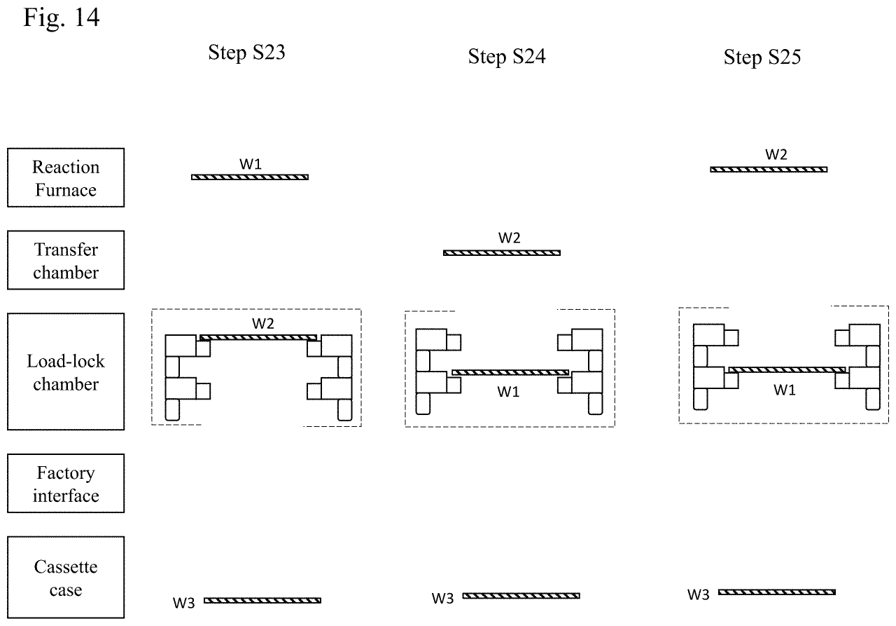

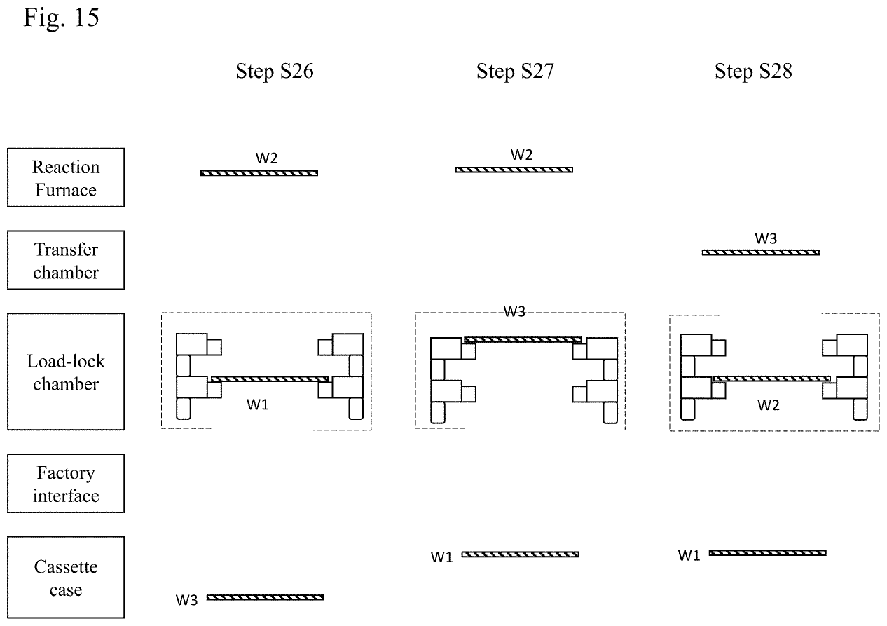

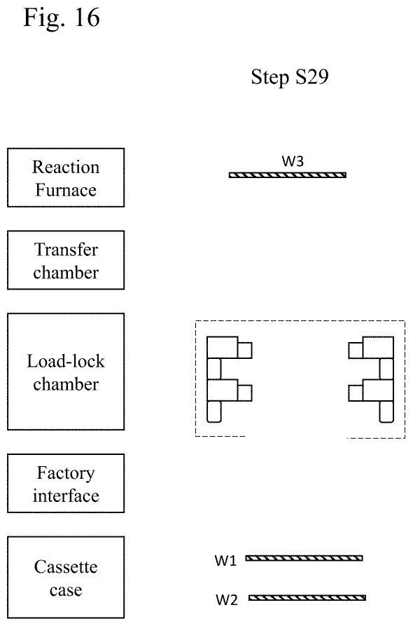

### BRIEF DESCRIPTION OF THE DRAWINGS

[FIG. 1] is a block diagram illustrating a vapor deposition device according to an embodiment of the present invention.

[FIG. 2A] is a plan view illustrating a carrier according to the embodiment of the present invention.

[FIG. 2B] is a cross-sectional view of the carrier, including a wafer and a reaction furnace susceptor.

[FIG. 3A] is a plan view illustrating a holder provided to a load-lock chamber.

[FIG. 3B] is a cross-sectional view of the holder of FIG. 3A including the wafer and the carrier.

[FIG. 3C] is a plan view illustrating a holder according to another example provided to a load-lock chamber.

[FIG. 3D] is a cross-sectional view of the holder of FIG. 3C including the wafer and the carrier.

[FIG. 4] is a plan view and cross-sectional views illustrating a transfer protocol for the wafer and the carrier in the load-lock chamber.

[FIG. 5] is a plan view and cross-sectional views illustrating a transfer protocol for the wafer and the carrier within a reaction chamber.

[FIG. 6A] is a plan view illustrating an example of a second blade attached to the tip of a hand of a second robot.

[FIG. 6B] is a cross-sectional view of the second blade including a wafer.

[FIG. 7A] is a plan view illustrating an example of a first blade attached to the tip of a hand of a first robot.

[FIG. 7B] is a cross-sectional view of the first blade including a carrier and a wafer.

[FIG. 8A] is a cross-sectional view illustrating a main part of a susceptor when a wafer is transported by using a carrier.

[FIG. 8B] is a cross-sectional view illustrating a main part of a susceptor when a wafer is transported without using a carrier.

[FIG. 9] is a diagram (no. 1) illustrating a handling protocol for the wafer and the carrier in the vapor deposition device of the embodiment.

[FIG. 10] is a diagram (no. 2) illustrating the handling protocol for the wafer and the carrier in the vapor deposition device of the embodiment.

[FIG. 11] is a diagram (no. 3) illustrating the handling protocol for the wafer and the carrier in the vapor deposition device of the embodiment.

[FIG. 12] is a diagram (no. 4) illustrating the handling protocol for the wafer and the carrier in the vapor deposition device of the embodiment.

[FIG. 13] is a diagram (no. 1) illustrating a handling protocol for the wafer without using the carrier in the vapor deposition device of the embodiment.

[FIG. 14] is a diagram (no. 2) illustrating a handling protocol for the wafer without using the carrier in the vapor deposition device of the embodiment.

[FIG. 15] is a diagram (no. 3) illustrating a handling protocol for the wafer without using the carrier in the vapor deposition device of the embodiment.

[FIG. 16] is a diagram (no. 4) illustrating a handling protocol for the wafer without using the carrier in the vapor deposition device of the embodiment.

### MODE FOR CARRYING OUT THE INVENTION

Hereafter, an embodiment of the present invention is described based on the drawings. FIG. 1 is a block diagram illustrating a vapor deposition device 1 according to the embodiment of the present invention. A main body of the vapor deposition device 1 shown in the center of the diagram is illustrated in a plan view. The vapor deposition device 1 of the present embodiment is what is known as a CVD device and is provided with a pair of reaction furnaces 11, 11; a wafer transfer chamber 12 in which is installed a first robot 121 that handles a wafer WF, such as a single crystal silicon wafer; a pair of load-lock chambers 13; a factory interface 14 in which is installed a second robot 141 that handles the wafer WF; and a load robot in which is installed a wafer storage container 15 (cassette case) in which a plurality of the wafers WF are stored.

The factory interface 14 is a zone configured to have the same air atmosphere as a clean room in which the wafer storage container 15 is mounted. The factory interface 14 is provided with the second robot 141, which extracts a before-treatment wafer WF that is stored in the wafer storage container 15 and deposits the wafer WF in the load-lock chamber 13, and also stores an after-treatment wafer WF transported to the load-lock chamber 13 in the wafer storage container 15. The second robot 141 is controlled by a second robot controller 142, and a second blade 143 mounted on a distal end of a robot hand displaces along a predetermined trajectory that has been taught in advance.

A first door 131 capable of opening and closing with an airtight seal is provided between the load-lock chamber 13 and the factory interface 14, while a second door 132 similarly capable of opening and closing with an airtight seal is provided between the load-lock chamber 13 and the wafer transfer chamber 12. In addition, the load-lock chamber 13 serves as a space where atmospheric gas exchange takes place between the wafer transfer chamber 12, which is configured to have an inert gas atmosphere, and the factory interface 14, which is configured to have an air atmosphere. Therefore, an exhaust device that evacuates an interior of the load lock chamber 13 to vacuum and a supply device that supplies inert gas to the load-lock chamber 13 are provided.

For example, when a before-treatment wafer WF is transported from the wafer storage container 15 to the wafer transfer chamber 12, in a state where the first door 131 on the factory interface 14 side is closed, the second door 132 on the wafer transfer chamber 12 side is closed, and the load-lock chamber 13 has an inert gas atmosphere, the wafer WF is extracted from the wafer storage container 15 using the second robot 141, the first door 131 on the factory interface 14 side is opened, and the wafer WF is transported to the load-lock chamber 13. Next, after the first door 131 on the factory interface 14 side is closed and the load-lock chamber 13 is restored to an inert gas atmosphere, the second door 132 on the wafer transfer chamber 12 side is opened and the wafer WF is transported to the wafer transfer chamber 12 using the first robot 121.

Conversely, when an after-treatment wafer WF is transported from the wafer transfer chamber 12 to the wafer storage container 15, in a state where the first door 131 on the factory interface 14 side is closed, the second door 132 on the wafer transfer chamber 12 side is closed, and the load-lock chamber 13 has an inert gas atmosphere, the second door 132 on the wafer transfer chamber 12 side is opened and the wafer WF in the wafer transfer chamber 12 is transported to the load-lock chamber 13 using the first robot 121. Next, after the second door 132 on the wafer transfer chamber 12 side is closed and the load-lock chamber 13 is restored to an inert gas atmosphere, the first door 131 on the factory interface 14 side is opened and the wafer WF is transported to the wafer storage container 15 using the second robot 141.

The wafer transfer chamber 12 is configured by a sealed chamber, connected on one side to the load-lock chamber 13 via the second door 132 that is capable of opening and closing and has an airtight seal, and connected on the other side via a gate valve 114 that is capable of opening and closing and has an airtight seal. The first robot 121, which transports the before-treatment wafer WF from the load-lock chamber 13 to the reaction chamber 111 and transports the after-treatment wafer WF from the reaction chamber 111 to the load-lock chamber 13, is installed on the wafer transfer chamber 12. The first robot 121 is controlled by a first robot controller 122, and a first blade 123 mounted on a distal end of a robot hand displaces along an operation trajectory that has been taught in advance.

An integrated controller 16 that integrates control of the entire vapor deposition device 1, the first robot controller 122, and the second robot controller 142 send and receive control signals amongst each other. In addition, when an operation command signal from the integrated controller 16 is sent to the first robot controller 122, the first robot controller 122 controls the operation of the first robot 121, and an operation result of the first robot 121 is sent from the first robot controller 122 to the integrated controller 16. Accordingly, the integrated controller 16 recognizes an operation status of the first robot 121. Similarly, when an operation command signal from the integrated controller 16 is sent to the second robot controller 142, the second robot controller 142 controls the operation of the second robot 141, and an operation result of the second robot 141 is sent from the second robot controller 142 to the integrated controller 16. Accordingly, the integrated controller 16 recognizes an operation status of the second robot 141.

Inert gas is supplied to the wafer transfer chamber 12 from an inert gas supply device not shown in the drawings, and gas in the wafer transfer chamber 12 is cleaned with a scrubber (scrubbing dust collector, precipitator) that is connected to an exhaust port, after which the gas is released outside the system. Although a detailed depiction is omitted, this type of scrubber can use a conventionally known pressurized water scrubber, for example.

The reaction furnace 11 is a device for growing an epitaxial film on a surface of the wafer WF using a CVD method, and includes a reaction chamber 111; a susceptor 112 on which the wafer WF is placed and rotated is provided inside the reaction chamber 111, and a gas supply device 113 is also provided that supplies hydrogen gas and raw material gas for growing a CVD film (when the CVD film is a silicon epitaxial film, the raw material gas may be silicon tetrachloride SiCl₄ or trichlorosilane SiHCl₃, for example) to the reaction chamber 111. In addition, although omitted from the drawings, a heat lamp for raising the temperature of the wafer WF to a predetermined temperature is provided around the circumference of the reaction chamber 111. Moreover, a gate valve 114 is provided between the reaction chamber 111 and the wafer transfer chamber 12, and airtightness with the wafer transfer chamber 12 of the reaction chamber 111 is ensured by closing the gate valve 114. Various controls, such as driving the susceptor 112 of the reaction furnace 11, supply and stoppage of gas by the gas supply device 113, turning the heat lamp on and off, and opening and closing the gate valve 114, are controlled by a command signal from the integrated controller 16. The vapor deposition device 1 shown in FIG. 1 depicts an example provided with a pair of reaction furnaces 11, 11, but the vapor deposition device 1 may have one reaction furnace 11 or three or more reaction furnaces.

A scrubber (scrubbing mist eliminator) having a similar configuration to that of the wafer transfer chamber 12 is provided to the reaction furnace 11. In other words, hydrogen gas or raw material gas supplied from the gas supply device 113 is cleaned by the scrubber connected to an exhaust port provided to the reaction chamber 111 and is then released outside the system. A conventionally known pressurized water scrubber, for example, can be used for this scrubber, as well.

In the vapor deposition device 1 according to the present embodiment, the wafer WF is transported between the load-lock chamber 13 and the reaction chamber 111 using a ring-shaped carrier C that supports the entire outer circumferential edge of the wafer WF. FIG. 2A is a plan view of the carrier C, FIG. 2B is a cross-sectional view of the carrier C including the wafer WF and the susceptor 112 of the reaction furnace 11, and FIG. 5 is a plan view and cross-sectional views illustrating a transfer protocol for the wafer WF and the carrier C within the reaction chamber 111.

The carrier C according to the present embodiment is configured by a material such as SiC, for example, is formed in an endless ring shape; and includes a bottom surface C11 that rests on a top surface of the susceptor 112 shown in FIG. 2B, a top surface C12 that touches and supports the entire outer circumferential edge of a reverse face of the wafer WF, an outer circumferential wall surface C13, and an inner circumferential wall surface C14. In addition, when the wafer WF supported by the carrier C is transported into the reaction chamber 111, in a state where the carrier C rests on the first blade 123 of the first robot 121 as illustrated in the plan view of FIG. 5A, the wafer WF is transported to a top portion of the susceptor 112 as illustrated in FIG. 5B, the carrier C is temporarily lifted by three or more carrier lifting pins 115 provided to the susceptor 112 so as to be capable of displacing vertically as illustrated in FIG. 5C, and the first blade 123 is retracted as illustrated in FIG. 5D, after which the susceptor 112 is raised as illustrated in FIG. 5E, thereby placing the carrier C on the top surface of the susceptor 112.

Conversely, when treatment in the reaction chamber 111 has ended for the wafer WF and the wafer WF is withdrawn in a state mounted on the carrier C, the susceptor 112 is lowered from the state illustrated in FIG. 5E and supports the carrier C with only the carrier lifting pins 115 as illustrated in FIG. 5D, the first blade 123 is advanced between the carrier C and the susceptor 112 as illustrated in FIG. 5C, and then the three carrier lifting pins 115 are lowered to rest the carrier C on the first blade 123 as illustrated in FIG. 5B, and the hand of the first robot 121 is operated. In this way, the wafer WF for which treatment has ended can be withdrawn in a state mounted on the carrier C.

Also, in the vapor deposition device 1 according to the present embodiment, the carrier C is transported between processes running from the load-lock chamber 13 to the reaction chamber 111, and therefore in the load-lock chamber 13, the before-treatment wafer WF is placed on the carrier C and the after-treatment wafer WF is removed from the carrier C. Therefore, a holder 17 that supports the carrier C at two vertical levels is provided to the load-lock chamber 13. FIG. 3A is a plan view illustrating the holder 17 that is provided to the load-lock chamber 13, and FIG. 3B is a cross-sectional view of the holder 17 including the carrier C. The holder 17 according to the present embodiment includes a fixed holder base 171; a first holder 172 and second holder 173 that support two carriers C at two vertical levels, and that are provided to the holder base 171 so as to be capable of lifting and lowering vertically; and three wafer lifting pins 174 that are provided to the holder base 171 so as to be capable of lifting and lowering vertically.

The first holder 172 and the second holder 173 (in the plan view of FIG. 3A, the second holder 173 is obscured by the first holder 172 and therefore only the first holder 172 is depicted) have projections for supporting the carrier C at four points, and one carrier C is placed on the first holder 172 and another carrier C is placed on the second holder 173. The carrier C that rests on the second holder 173 is inserted into a gap between the first holder 172 and the second holder 173. In particular, as shown in FIG. 3B, the distance L between the tip of the first holder 172 and the tip of the second holder 173 facing each other is formed to be smaller than the diameter of the wafer WF so that the first holder 172 and the second holder 173 of the present embodiment can support not only the carrier C but also the wafer WF. As a result, the wafer WF can be handled by the holder 17 in the load-lock chamber 13 without using a carrier, and thus the compatibility is improved.

FIG. 3C is a plan view illustrating another example of the holder 17 provided in the load-lock chamber 13, and FIG. 3D is a cross-sectional view of the holder 17 of FIG. 3C including the wafer WF. The holder 17 of the present embodiment comprises a fixed holder base 171, a first holder 172 and a second holder 173 which are carrier holders that is provided so as to be able to move up and down with respect to the holder base 171 and supports two carriers C in two upper and lower stages, and three wafer lift pins 174 that can move up and down with respect to the holder base 171. Each of the first holder 172 and the second holder 173 as carrier holders comprises a first wafer holder 172a and a second wafer holder 173a which are wafer holders that support two wafer WF in two upper and lower stages.

The first holder 172 which is a carrier holder supports only the carrier C at four points, and one carrier C is mounted on the first holder 172. The second holder 173 which is a carrier holder also supports only the carrier C at four points, and one carrier C is mounted on the second holder 173. Further, as shown in FIG. 3C, the first holder 172 and the second holder 173 support the carrier C at four points, but the first holder 172 and the second holder 173 may support the carrier C at four points or more.

On the other hand, the first wafer holder 172a which is a wafer holder supports only the wafer WF at four points, and one wafer WF is mounted on the first wafer holder 172a. The second wafer holder 173a which is a wafer holder also supports only the wafer WF at four points, and one wafer WF is mounted on the second wafer holder 173a. Further, as shown in FIG. 3C, the first wafer holder 172a and the second wafer holder 173a support the wafer WF at four points, but the first wafer holder 172a and the second wafer holder 173a may support the wafer WF at four points or more.

As shown in FIG. 3C, the first holder 172 and the second holder 173 may support the carrier C at at least two points on the left and right sides respectively, and the first wafer holder 172a and the second wafer holder 173a may support the wafer WF at at least two points on the left and right sides respectively. Further, the points where the first wafer holder 172a and the second wafer holder 173a support the wafer WF on the left and right sides respectively may be set outside the points where the first holder 172 and the second holder 173 support the carrier C on the left and right sides respectively. By providing the points where the wafer holder supports the wafer WF on the outer side, that is, by providing a wide pitch at each of the two points on the left and right, the points supporting the wafer WF approach equal distribution, and the support of the wafer WF is stabilized.

FIG. 4 is a plan view and cross-sectional views of a transfer protocol for the wafer WF and carrier C in the load-lock chamber 13 and depicts a protocol in which a before-treatment wafer WF rests on the carrier C in a state where the carrier C is supported by the first holder 172, as illustrated in FIG. 4B. In other words, the second robot 141 that is provided to the factory interface 14 loads one wafer WF that is stored in the wafer storage container 15 onto the second blade 143 and transports the wafer WF via the first door 131 of the load-lock chamber 13 to a top portion of the holder 17, as illustrated in FIG. 4B. Next, as illustrated in FIG. 4C, the three wafer lifting pins 174 are raised relative to the holder base 171 and temporarily hold up the wafer WF, and the second blade 143 is retracted as illustrated in FIG. 4D. The three wafer lifting pins 174 are provided in positions that do not interfere with the second blade 143, as illustrated in the plan view of FIG. 4A. Next, as illustrated in FIGS. 4D and 4E, the three wafer lifting pins 174 are lowered and the first holder 172 and the second holder 173 are raised, whereby the wafer WF is placed on the carrier C.

Conversely, when the after-treatment wafer WF transported to the load-lock chamber 13 in a state resting on the carrier C is transported to the wafer storage container 15, as illustrated in FIG. 4D, the three wafer lifting pins 174 are raised and the first holder 172 and the second holder 173 are lowered from the state illustrated in FIG. 4E, the wafer WF is supported by only the wafer lifting pins 174, and the second blade 143 is advanced between the carrier C and the wafer WF as illustrated in FIG. 4C, after which the three wafer lifting pins 174 are lowered to load the wafer WF on the second blade 143 as illustrated in FIG. 4B, and the hand of the second robot 141 is operated. In this way, the wafer WF for which treatment has ended can be taken out of the carrier C and into the wafer storage container 15. In the state illustrated in FIG. 4E, the wafer WF for which treatment has ended is transported to the first holder 172 in a state resting on the carrier C, but the wafer WF can be taken out of the carrier C and into the wafer storage container 15 with a similar protocol when the wafer WF is transported to the second holder 173, as well.

FIG. 6A is a plan view illustrating an example of a second blade 143 attached to the tip of a hand of a second robot 141, FIG. 6B is a cross-sectional view of the second blade 143 including a wafer WF. In the second blade 143 of the present embodiment, a first recess 144 having a diameter corresponding to the wafer WF is formed on one surface of a strip-shaped main body. The diameter of the first recess 144 is formed to be slightly larger than the diameter of the wafer WF. Then, the second robot 141 mounts the wafer WF in the first recess 144 when the wafer WF is taken out from the wafer storage container 15 and when the wafer WF is stored into the wafer storage container 15.

FIG. 7A is a plan view illustrating an example of a first blade 123 attached to the tip of a hand of a first robot 121, FIG. 7B is a cross-sectional view of the first blade 123 including a carrier C and a wafer WF. The first blade 123 of the present embodiment has a first recess 124 having a diameter corresponding to the outer circumferential wall surface C13 of the carrier C on one surface of a strip-shaped main body, and an outer shape of a wafer WF on the bottom surface of the first recess 124. The second recess 125 having a diameter corresponding to the above is formed concentrically. The diameter of the first recess 124 is formed to be slightly larger than the diameter of the outer circumferential wall surface C13 of the carrier C, and the diameter of the second recess 125 is formed to be slightly larger than the outer diameter of the wafer WF.

Then, when the first robot 121 transports the carrier C on which the wafer WF is mounted, the first robot 121 mounts the carrier C on the first recess 124. When only the wafer WF is transported without using the carrier C, the wafer WF can be mounted in the second recess 125. In this way, the carrier C and the wafer WF can be reliably supported by one first blade 123. Therefore, when switching between the case where the process is executed using the carrier C and the case where the process is executed without using the carrier C, it is not necessary to exchange the first blade 123 or to provide the first robot 121 with two hands. As a result, the compatibility of the vapor deposition device 1 is high.

The vapor deposition device 1 of the present embodiment transport the WF by using a carrier C to suppress damage and unevenness caused by the wafer lift pin provided on the susceptor 112 of the reaction chamber 111 coming into contact with the back surface of the wafer WF. When the carrier C is insufficient for some reason, or when the order of the wafer production fluctuates, it may be desired to transport the wafer WF without using the carrier C. Therefore, as described above, the holder 17 of the load-lock chamber 13 can support not only the carrier C but also the wafer WF, and the first blade 123 can support not only the carrier C but also the wafer WF. Further, in addition to these, the susceptor 112 of the reactor 11 is also configured so that the process can be easily switched between the case where the process is executed using the carrier C and the case where the process is executed without using the carrier C.

FIG. 8A is a cross-sectional view illustrating a main part of a surrounding construction of a susceptor when a wafer WF is transported by using a carrier C. The susceptor 112 is fixed and supported at the upper end of the support shaft 116 that is rotated by the rotation drive unit 119a. Further, the shaft portion of the support shaft 116 is inserted into the shaft portion of the lift shaft 117, and a first mounting portion 1171 to which the carrier lift pin 115 for lifting and lowering the carrier C is mounted is formed at the upper end of the lift shaft 117. The lift shaft 117 rotates together with the support shaft 116, and is moved up and down between the lifting position and the lowering position by the lifting drive unit 119b. Further, when the carrier lift pin 115 is mounted on the first mounting portion 1171 of the lift shaft 117, the first through hole 1161 is formed at a position penetrating the support shaft 116.

Then, when the CVD film is formed in the reaction chamber 111, as shown in FIG. 8A, the support shaft 116 is rotated by the rotation drive unit 119a in a state where the carrier lift pin 115 is lowered to the lowering position by the lifting drive unit 119b. On the other hand, when the carrier C on which the wafer WF is mounted is mounted on the susceptor 112 or when the carrier C mounted on the susceptor 112 is carried out, the lift shaft 117 is moved to the transport position by the lifting drive unit 119b and the carrier lift pin 115 receives and lifts the carrier C.

In particular, the lift shaft 117 of the present embodiment is formed with a second mounting portion 1172 on which a wafer lift pin 118 for lifting and lowering the wafer WF can be mounted, assuming a case where the wafer WF is transported without using the carrier C. Further, when the wafer lift pin 118 is mounted on the second mounting portion 1172 of the lift shaft 117, the second through hole 1162 is formed at a position penetrating the support shaft 116. FIG. 8B is a cross-sectional view illustrating a main part of the surrounding construction of a susceptor 112 when a wafer WF is transported without using a carrier C. When the wafer WF is transported without using the carrier C, the susceptor 112 is replaced with a dedicated part, the carrier lift pin 115 is removed, and the wafer lift pin 118 is mounted on the second mounting portion 1172.

At this time, since the second through hole 1162 is formed in advance in the support shaft 116 and the second mounting portion 1172 is formed in advance in the lift shaft 117, these support shaft 116 and lift shaft 117 can be shared.

Then, when the CVD film is formed in the reaction chamber 111, as shown in FIG. 8B, the support shaft 116 is rotated by the rotation drive unit 119a in a state where the wafer lift pin 118 is lowered to the lowering position by the lifting drive unit 119b. On the other hand, when the wafer WF is mounted on the susceptor 112 or when the wafer WF mounted on the susceptor 112 is carried out, the susceptor 112 is moved to the transport position by the lifting drive unit 119b, and the wafer WF is received by the wafer lift pin 118.

Next a protocol is described for handling the carrier C and the wafer WF prior to creating the epitaxial film (hereafter referred to simply as “before-treatment”) and after creating the epitaxial film (hereafter referred to simply as “after-treatment”) in the vapor deposition device 1 according to the present embodiment. FIGS. 9 to 12 are schematic views illustrating a handling protocol for a wafer WF and a carrier C in the vapor deposition device of the present embodiment and correspond to the wafer storage container 15 on one side of the device, the load-lock chamber 13, and the reaction furnace 11 in FIG. 1; a plurality of wafers W1, W2, W3, . . . (for example, a total of 25 wafers) are stored in the wafer storage container 15 and treatment is initiated in that order. FIGS. 9 to 12 show a case of transporting the wafer WF by using the carrier C.

Step S0 in FIG. 9 shows a standby state from which treatment using the vapor deposition device 1 is to begin, and has the plurality of wafers W1, W2, W3, . . . (for example, a total of 25 wafers) stored in the wafer storage container 15, has an empty carrier C1 supported by the first holder 172 of the load-lock chamber 13, has an empty carrier C2 supported by the second holder 173, and has an inert gas atmosphere in the load-lock chamber 13.

In the next step (step 51), the second robot 141 loads the wafer W1 that is stored in the wafer storage container 15 onto the second blade 143 and transfers the wafer W1 through the first door 131 of the load-lock chamber 13 to the carrier C1 that is supported by the first holder 172. The protocol for this transfer was described with reference to FIG. 4.

In the next step (step S2), the first door 131 of the load-lock chamber 13 is closed and, in a state where the second door 132 is also closed, the interior of the load-lock chamber 13 undergoes gas exchange to the inert gas atmosphere. Then, the second door 132 is opened, the carrier C1 is loaded onto the first blade 123 of the first robot 121, the gate valve 114 of the reaction furnace 11 is opened, and the carrier C1 on which the wafer W1 is mounted is transferred through the gate valve 114 to the susceptor 112. The protocol for this transfer was described with reference to FIG. 4. In steps S2 to S4, the CVD film creation process is performed on the wafer W1 in the reaction furnace 11.

In other words, the carrier C1 on which the before-treatment wafer W1 is mounted is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W1 in the reaction chamber 111 is heated to a predetermined temperature by the heat lamp and pretreatment such as etching or heat treatment is performed as necessary, after which the gas supply device 113 supplies raw material gas while controlling the flow volume and/or supply time. This creates a CVD film on the surface of the wafer W1. Once the CVD film is formed, the gas supply device 113 once again supplies the reaction chamber 111 with hydrogen gas and the reaction chamber undergoes gas exchange to a hydrogen gas atmosphere, after which the protocol stands by for a predetermined amount of time.

While the reaction furnace 11 is treating the wafer W1 in steps S2 to S4, the second robot 141 extracts the next wafer (W2) from the wafer storage container 15 and prepares for the next treatment. Prior to this, in step S3 in the present embodiment, the second door 132 of the load-lock chamber 13 is closed, and in a state where the first door 131 is also closed, the interior of the load-lock chamber 13 undergoes gas exchange to an inert gas atmosphere. Then, the second door 132 is opened, the carrier C2 supported by the second holder 173 is transferred to the first holder 172 by the first robot 121. Subsequently, in step S4, the second robot 141 loads the wafer W2 that was stored in the wafer storage container 15 onto the second blade 143, the first door 131 is opened, and the wafer W2 is transferred to the carrier C2 that is supported by the first holder 172 of the load-lock chamber 13.

In this way, in the present embodiment, step S3 is added and the before-treatment wafer WF that was stored in the wafer storage container 15 is mounted on the first holder 172, which is the topmost-level holder of the holder 17 of the load-lock chamber 13. This is for the following reasons. Specifically, as illustrated in step S2, when the empty carrier C2 on which the next wafer W2 is to be mounted is supported by the second holder 173, once the wafer W2 is mounted on the carrier C2, there is a possibility that the after-treatment wafer W1 may be transferred to the first holder 172. The carrier C of the vapor deposition device 1 according to the present embodiment is transported to the reaction chamber 111, and therefore the carrier C is a factor in particle production, and when the carrier C1 is held above the before-treatment wafer W2, dust may fall on the before-treatment wafer W2. Therefore, step S3 is added and the empty carrier C2 is transferred to the first holder 172 so that the before-treatment wafer WF is mounted on the topmost-level holder (first holder 172) of the holder 17 of the load-lock chamber 13.

In step S5, the first door 131 of the load-lock chamber 13 is closed and, in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C1 on which the after-treatment wafer W1 is mounted, the carrier C1 is withdrawn from the reaction chamber 111, and the gate valve 114 is closed, after which the second door 132 is opened and the carrier C1 is transferred to the second holder 173 of the load-lock chamber 13. Subsequently, the carrier C2 supported by the first holder 172 is loaded onto the first blade 123 of the first robot 121 and, as illustrated in step S6, the gate valve 114 is opened and the carrier C2 on which the before-treatment wafer W2 is mounted is transferred through the wafer transfer chamber 12 to the susceptor 112 of the reaction furnace 11.

In steps S6 to S9, the CVD film creation process is performed on the wafer W2 in the reaction furnace 11. In other words, the carrier C2 on which the before-treatment wafer W2 is mounted is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W2 in the reaction chamber 111 is heated to a predetermined temperature by the heat lamp and pretreatment such as etching or heat treatment is performed as necessary, after which the gas supply device 113 supplies raw material gas while controlling the flow volume and/or supply time. This creates a CVD film on the surface of the wafer W2. Once the CVD film is formed, the gas supply device 113 once again supplies the reaction chamber 111 with hydrogen gas and the reaction chamber 111 undergoes gas exchange to a hydrogen gas atmosphere, after which the protocol stands by for a predetermined amount of time.

In this way, while the reaction furnace 11 is treating the wafer W2 in steps S6 to S9, the second robot 141 stores the after-treatment wafer W1 in the wafer storage container 15 and also extracts the next wafer (W3) from the wafer storage container 15 and prepares for the next treatment. In other words, in step S7, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the after-treatment wafer W1 onto the second blade 143 from the carrier C1 supported by the second holder 173 and, as illustrated in step S8, the after-treatment wafer W1 is stored in the wafer storage container 15. Subsequently, similarly to step S3 described above, in step S7, the carrier C1 supported by the second holder 173 is transferred to the first holder 172 by the first robot 121.

Subsequently, in step S8, the second robot 141 loads the wafer W3 that was stored in the wafer storage container 15 onto the second blade 143 and, as illustrated in step S9, the first door 131 is opened and the wafer W3 is transferred to the carrier C1 that is supported by the first holder 172 of the load-lock chamber 13.

In step S10, similarly to step S5 described above, the first door 131 of the load-lock chamber 13 is closed, and in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C2 on which the after-treatment wafer W2 is mounted, and the gate valve 114 is closed, after which the second door 132 is opened and the carrier C2 is transferred from the reaction chamber 111 to the second holder 173 of the load-lock chamber 13. Subsequently, the carrier C1 supported by the first holder 172 is loaded onto the first blade 123 of the first robot 121 and, as illustrated in step S11, the carrier C1 on which the before-treatment wafer W3 is mounted is transferred through the wafer transfer chamber 12 to the susceptor 112 of the reaction furnace 11.

In step S10, similarly to step S7 described above, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the post-treatment wafer W2 onto the second blade 143 from the carrier C2 that is supported on the second holder 173 and, as illustrated in step S11, the post-treatment wafer W2 is stored in the wafer storage container 15. Thereafter, the above steps are repeated until treatment for all of the before-treatment wafers WF stored in the wafer storage container 15 ends.

In the vapor deposition device 1 according to the present embodiment, while treatment is ongoing in the reaction furnace 11, the next before-treatment wafer WF is extracted from the wafer storage container 15 and prepared, the after-treatment wafer WF is stored in the wafer storage container 15, and the like, and so the amount of time consumed simply in transport is drastically reduced. In such a case, when a number of standby carriers C in the load lock chamber 13 is set to two or more, as with the holder 17 in the present embodiment, a degree of freedom in shortening the amount of time consumed simply in transport can be substantially increased. Furthermore, when the space dedicated to the load-lock chamber 13 is considered, aligning the plurality of carriers C in multiple vertical levels reduces the space dedicated to the vapor deposition device 1 overall as compared to aligning the plurality of carriers C left-to-right. But, when the plurality of carriers C are aligned in multiple vertical levels, the carrier C may be held above a before-treatment wafer WF and dust may fall on the before-treatment wafer WF. However, in the vapor deposition device 1 according to the present embodiment, steps S3 and S8 are added and the empty carrier C2 is transferred to the first holder 172 so that the before-treatment wafer WF is mounted on the topmost-level holder (first holder 172) of the holder 17 of the load-lock chamber 13, and therefore the before-treatment wafer WF is mounted on the topmost-level carrier C. As a result, particles originating from the carrier C can be inhibited from adhering to the wafer WF and LPD quality can be improved.

In addition, in the vapor deposition device 1 of the present embodiment, the wafer WF can be transported without using the carrier C. FIGS. 13 to 16 are schematic views showing a procedure for handling the wafer WF in the vapor deposition device 1 of the present embodiment. FIGS. 13 to 16 correspond to the wafer storage container 15, the load-lock chamber 13 and the reaction furnace 11 on one side of FIG. 1. In FIGS. 13 to 16, a plurality of wafers W1, W2, W3 . . . (For example, a total of 25) are stored in the wafer storage container 15, and the processing is started in this order. FIGS. 13 to 16 show a case where the wafer WF is transported without using the carrier C.

Step S20 in FIG. 13 shows a standby state from which treatment using the vapor deposition device 1 is to begin, and has the plurality of wafers W1, W2, W3, . . . (for example, a total of 25 wafers) stored in the wafer storage container 15, has an empty carrier C1 supported by the first holder 172 of the load-lock chamber 13, has an empty carrier C2 supported by the second holder 173, and has an inert gas atmosphere in the load-lock chamber 13. As described above, both the first holder 172 and the second holder 173 are configured to be able to support the wafer WF too.

In the next step (step S21), the second robot 141 loads the wafer W1 that is stored in the wafer storage container 15 onto the first recess 144 of the second blade 143 and transfers the wafer W1 through the first door 131 of the load-lock chamber 13 to the first holder 172.

In the next step (step S22), the first door 131 of the load-lock chamber 13 is closed and, in a state where the second door 132 is also closed, the interior of the load-lock chamber 13 undergoes gas exchange to the inert gas atmosphere. Then, the second door 132 is opened, the wafer WF is loaded onto the second recess 125 of the first blade 123 of the first robot 121, the gate valve 114 of the reaction furnace 11 is opened, and the wafer W1 is transferred through the gate valve 114 to the susceptor 112. As shown in FIG. 8, the surrounding construction of the susceptor 112 is exchanged.

In other words, the before-treatment wafer W1 is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W1 in the reaction chamber 111 is heated to a predetermined temperature by the heat lamp and pretreatment such as etching or heat treatment is performed as necessary, after which the gas supply device 113 supplies raw material gas while controlling the flow volume and/or supply time. This creates a CVD film on the surface of the wafer W1. Once the CVD film is formed, the gas supply device 113 once again supplies the reaction chamber 111 with hydrogen gas and the reaction chamber undergoes gas exchange to a hydrogen gas atmosphere, after which the protocol stands by for a predetermined amount of time.

While the reaction furnace 11 is treating the wafer W1 in steps S22 to S23, the second robot 141 extracts the next wafer (W2) from the wafer storage container 15 and prepares for the next treatment. That is, in step S23, the second door 132 of the load-lock chamber 13 is closed, and in a state where the first door 131 is also closed, the interior of the load-lock chamber 13 undergoes gas exchange to an inert gas atmosphere. Then, the second robot 141 loads the wafer W2 that was stored in the wafer storage container 15 onto the first recess 144 of the second blade 143, the first door 131 is opened, and the wafer W2 is transferred to the first holder 172 of the load-lock chamber 13.

In step S24, the first door 131 of the load-lock chamber 13 is closed and, in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the after-treatment wafer W1 on the second recess 125, the wafer W1 is withdrawn from the reaction chamber 111, and the gate valve 114 is closed, after which the second door 132 is opened and the wafer W1 is transferred to the second holder 173 of the load-lock chamber 13. Subsequently, the wafer W2 supported by the first holder 172 is loaded onto the second recess 125 of the first blade 123 of the first robot 121 and, as illustrated in steps S24 to S25, the before-treatment wafer W2 is transferred through the wafer transfer chamber 12 to the susceptor 112 of the reaction furnace 11.

In steps S25 to S27, the CVD film creation process is performed on the wafer W2 in the reaction furnace 11. In other words, the before-treatment wafer W2 is transferred to the susceptor 112 of the reaction chamber 111 and the gate valve 114 is closed, and after waiting a predetermined amount of time, the gas supply device 113 supplies hydrogen gas to the reaction chamber 111, giving the reaction chamber 111 a hydrogen gas atmosphere. Next, the wafer W2 in the reaction chamber 111 is heated to a predetermined temperature by the heat lamp and pretreatment such as etching or heat treatment is performed as necessary, after which the gas supply device 113 supplies raw material gas while controlling the flow volume and/or supply time. This creates a CVD film on the surface of the wafer W2. Once the CVD film is formed, the gas supply device 113 once again supplies the reaction chamber 111 with hydrogen gas and the reaction chamber 111 undergoes gas exchange to a hydrogen gas atmosphere, after which the protocol stands by for a predetermined amount of time.

In this way, while the reaction furnace 11 is treating the wafer W2 in steps S25 to S27, the second robot 141 stores the after-treatment wafer W1 in the wafer storage container 15 and also extracts the next wafer (W3) from the wafer storage container 15 and prepares for the next treatment. In other words, in step S26, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the after-treatment wafer W1 supported by the second holder 173 onto the first recess 144 of the second blade 143 and, as illustrated in step S27, the after-treatment wafer W1 is stored in the wafer storage container 15. Subsequently, in step S27, the wafer W3 stored in the wafer storage container 15 is leaded on the first recess 144 of the second blade 143 and is transferred to the first holder 172 of the load-lock chamber 13 through the opened first door 131 by the first robot 121.

In step S28, the first door 131 of the load-lock chamber 13 is closed, and in a state where the second door 132 is also closed, the interior of the load-lock chamber 13 undergoes gas exchange to an inert gas atmosphere. Then, the gate valve 114 of the reaction furnace 11 is opened, the first blade 123 of the first robot 121 is inserted into the reaction chamber 111 and is loaded with the carrier C2 on which the after-treatment wafer W2 is mounted, and the gate valve 114 is closed, after which the second door 132 is opened and the carrier C2 is transferred from the reaction chamber 111 to the second holder 173 of the load-lock chamber 13. Subsequently, the carrier C1 supported by the first holder 172 is loaded onto the first blade 123 of the first robot 121 and, as illustrated in step S11, the carrier C1 on which the before-treatment wafer W3 is mounted is transferred through the wafer transfer chamber 12 to the susceptor 112 of the reaction furnace 11.

In step S29, the second door 132 of the load-lock chamber 13 is closed, and in a state where the first door 131 is also closed, the interior of the load-lock chamber 13 undergoes gas exchange to an inert gas atmosphere. Then, the first door 131 is opened, the second robot 141 loads the post-treatment wafer W2 onto the first recess 144 of the second blade 143 from the second holder 173 and the post-treatment wafer W2 is stored in the wafer storage container 15. Thereafter, the above steps are repeated until treatment for all of the before-treatment wafers WF stored in the wafer storage container 15 ends.

As described above, the vapor deposition device 1 of the present embodiment can easily switch by performing the minimum setup between the case where the wafer WF is transported using the carrier C and the case where the wafer WF is transported without using the carrier C.

### DESCRIPTION OF REFERENCE NUMERALS

1 . . . Vapor deposition device
11 . . . Reaction furnace
111 . . . Reaction chamber
112 . . . Susceptor
113 . . . Gas supply device
114 . . . Gate valve
115 . . . Carrier lifting pin
116 . . . Support shaft
1161 . . . First through hole
1162 . . . Second through hole
117 . . . Lift shaft
1171 . . . First mounting portion
1172 . . . Second mounting portion
118 . . . Wafer lifting pin
119a . . . rotation drive unit
119b . . . lifting drive unit
12 . . . Wafer transfer chamber
121 . . . First robot
122 . . . First robot controller
123 . . . First blade
124 . . . First recess
125 . . . Second recess
13 . . . Load-lock chamber
131 . . . First door
132 . . . Second door
14 . . . Factory interface
141 . . . Second robot
142 . . . Second robot controller
143 . . . Second blade
144 . . . First recess
15 . . . Wafer storage container
16 . . . Integrated controller
17 . . . Holder
171 . . . Holder base
172 . . . First holder
172a . . . First wafer holder
173 . . . Second holder
173a . . . Second wafer holder
174 . . . Wafer lifting pin
C . . . Carrier
C11 . . . Bottom surface
C12 . . . Top surface
C13 . . . Outer circumferential wall surface
C14 . . . Inner circumferential wall surface
WF . . . Wafer

1. A vapor deposition device which is provided with a ring-shaped carrier that supports an outer edge of a wafer, and which uses a plurality of the carriers to:
transport a plurality of before-treatment wafers from a wafer storage container, through a factory interface, load-lock chamber, and wafer transfer chamber, to a reaction chamber in that order, and
transport a plurality of after-treatment wafers from the reaction chamber, through the wafer transfer chamber, load-lock chamber, and factory interface, to the wafer storage container in that order,
and in which the load-lock chamber communicates with the factory interface via a first door and also communicates with the wafer transfer chamber via a second door,
the wafer transfer chamber communicates, via a gate valve, with the reaction chamber in which a CVD film is formed on the wafer,
the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber,
the factory interface is provided with a second robot that extracts a before-treatment wafer from the wafer storage container and mounts the wafer on a carrier standing by in the load-lock chamber, and also stores in the wafer storage container an after-treatment wafer mounted on the carrier that has been transported to the load-lock chamber, and
the load-lock chamber is provided with a holder that supports the carrier,
wherein the first robot is provided with a first blade at a tip,
the first blade comprises:
a first recess which supports the carrier; and
a second recess which is provided at a bottom surface of the first recess to support the wafer.

2. The vapor deposition device according to claim 1, wherein the first recess is a recess corresponding to a part of the outer circumferential wall surface of the carrier, and the second recess is a recess corresponding to a part of an outer shape of the wafer.

3. The vapor deposition device according to claim 1 erg, wherein the first recess and the second recess are formed concentrically.

4. A vapor deposition device which is provided with a ring-shaped carrier that supports an outer edge of a wafer, and which uses a plurality of the carriers to:
transport a plurality of before-treatment wafers from a wafer storage container, through a factory interface, load-lock chamber, and wafer transfer chamber, to a reaction chamber in that order, and
transport a plurality of after-treatment wafers from the reaction chamber, through the wafer transfer chamber, load-lock chamber, and factory interface, to the wafer storage container in that order,
and in which the load-lock chamber communicates with the factory interface via a first door and also communicates with the wafer transfer chamber via a second door,
the wafer transfer chamber communicates, via a gate valve, with the reaction chamber in which a CVD film is formed on the wafer,
the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber, and
the factory interface is provided with a second robot that extracts a before-treatment wafer from the wafer storage container and mounts the wafer on a carrier standing by in the load-lock chamber, and also stores in the wafer storage container an after-treatment wafer mounted on the carrier that has been transported to the load-lock chamber,
wherein the load-lock chamber is provided with a holder which can support the carrier and the wafer.

5. The vapor deposition device according to claim 4, wherein the holder includes a carrier holder which supports the carrier and a wafer holder which supports the wafer.

6. The vapor deposition device according to claim 5, wherein
the carrier holder supports the carrier at at least two points on each of a left side and a right side,
the wafer holder supports the wafer at at least two points on each of a left side and a right side,
the points at which the wafer holder supports the wafer at on each of the left side and the right side is set outside the points at which the carrier holder supports the carrier on each of the left side and the right side.

7. The vapor deposition device according to claim 4, wherein the first robot is provided with a first blade at a tip,
the first blade comprises:
a first recess which supports the carrier; and
a second recess which is provided at a bottom surface of the first recess to support the wafer.

8. A vapor deposition device which is provided with a ring-shaped carrier that supports an outer edge of a wafer, and which uses a plurality of the carriers to:
transport a plurality of before-treatment wafers from a wafer storage container, through a factory interface, load-lock chamber, and wafer transfer chamber, to a reaction chamber in that order, and
transport a plurality of after-treatment wafers from the reaction chamber, through the wafer transfer chamber, load-lock chamber, and factory interface, to the wafer storage container in that order,
and in which the load-lock chamber communicates with the factory interface via a first door and also communicates with the wafer transfer chamber via a second door,
the wafer transfer chamber communicates, via a gate valve, with the reaction chamber in which a CVD film is formed on the wafer,
the wafer transfer chamber is provided with a first robot that deposits a before-treatment wafer transported into the load-lock chamber into the reaction chamber in a state where the before-treatment wafer is mounted on a carrier and also withdraws an after-treatment wafer for which treatment in the reaction chamber has ended from the reaction chamber in a state where the after-treatment wafer is mounted on a carrier and transports the wafer to the load-lock chamber,
the factory interface is provided with a second robot that extracts a before-treatment wafer from the wafer storage container and mounts the wafer on a carrier standing by in the load-lock chamber, and also stores in the wafer storage container an after-treatment wafer mounted on the carrier that has been transported to the load-lock chamber, and
the load-lock chamber is provided with a holder that supports the carrier,
wherein the reaction chamber is provided with a support shaft which supports a susceptor and rotates by a rotation drive unit and a lift shaft which moves up and down with respect to the support shaft by a lifting drive unit,
the lift shaft is provided with a first mounting portion on which a carrier lifting pin can be mounted and a second mounting portion on which a wafer lifting pin can be mounted,
the support shaft is provided with a first through hole through which the carrier lifting pin mounted on the first mounting portion can penetrate and a second through hole through which the wafer lifting pin mounted on the second mounting portion can penetrate.

9. The vapor deposition device according to claim 8, wherein a shaft portion of the support shaft is inserted into a shaft portion of the lift shaft, and the lift shaft rotates and moves up and down together with the support shaft.

10. The vapor deposition device according to claim 8, wherein the first robot is provided with a first blade at a tip,
the first blade comprises:
a first recess which supports the carrier; and
a second recess which is provided at a bottom surface of the first recess to support the wafer.

11. The vapor deposition device according to claim 8, wherein the load-lock chamber is provided with a holder which can support the carrier and the wafer.
